(19) United States
(12) Patent Application Publication
(10) Pub. No.: US 2025/0111107 A1
(43) Pub. Date: Apr. 3, 2025

(54) SYSTEMS AND METHODS FOR GENERATING DESIGNS USING ANALOGICS WITH LEARNING MODELS

(71) Applicant: Toyota Research Institute, Inc., Los Altos, CA (US)

(72) Inventors: Chuan-En Lin, Pittsburgh, PA (US); Hyeonsu B. Kang, Pittsburgh, PA (US); Nikolas A. Martelaro, Pittsburgh, PA (US); Aniket D. Kittur, Pittsburgh, PA (US); Yin-Ying Chen, San Jose, CA (US); Matthew K. Hong, Mountain View, CA (US)

(73) Assignees: Toyota Research Institute, Inc., Los Altos, CA (US); Toyota Jidosha Kabushiki Kaisha, Toyota-shi Aichi-ken (JP); Carnegie Mellon University, Pittsburgh, PA (US)

(21) Appl. No.: 18/591,578

(22) Filed: Feb. 29, 2024

Related U.S. Application Data
(60) Provisional application No. 63/586,632, filed on Sep. 29, 2023.
(60) Provisional application No. 63/556,088, filed on Feb. 21, 2024.

(51) Int. Cl. G06F 30/27

(52) U.S. Cl. CPC G06F 30/27

(57) ABSTRACT

Systems, methods, and other embodiments described herein relate to generating designs using learning models for analogics that process text and sketch-based inputs. In one embodiment, a method includes estimating analogical suggestions using a transformer model for a text prompt having design parameters. The method also includes generating an image using a learning model for an expression selected from the analogical suggestions and a sketched stroke inputted. The method also includes manipulating a modified sketch by the learning model and the modified sketch is derived from a sketched conversion of the image by an edge model.

### CROSS-REFERENCE TO RELATED APPLICATIONS

This application claims benefit of U.S. Provisional Application No. 63/586,632, filed on Sep. 29, 2023 and U.S. Provisional Application No. 63/556,088, filed on Feb. 21, 2024, which are herein incorporated by reference in their entirety.

### TECHNICAL FIELD

The subject matter described herein relates, in general, to generating designs using analogics, and, more particularly, to generating designs using learning models for analogics that process text and sketch-based inputs.

### BACKGROUND

Systems for designing objects and products use advanced tools having graphic engines that can expedite development cycles. Graphic engines allow designers to manipulate design sketches and collaborate with stakeholders. However, these tools demand that designers perform substantial duties during development, such as concept research, shaping, and part selection. Therefore, development cycles become extended and delayed, particularly with complex products (e.g., vehicles) using the advanced tools.

In various implementations, systems implement learning models to manipulate a design sketch and generate a product concept. For example, a learning model automatically generates shapes for a part that completes a vehicle. However, these systems encounter difficulties extracting and understanding salient features from the design sketch. As such, the learning models rely on other inputs that are parsable to augment design sketches and conform with design goals. This approach may still encounter difficulties in enhancing a generated image through multiple iterations. Therefore, systems designing objects using learning models that factor parsable inputs and sketches encounter difficulties at efficiently producing robust and viable designs.

### SUMMARY

In one embodiment, example systems and methods generating designs using learning models for analogics that process text and sketch-based inputs are disclosed. In various implementations, designers use learning models that create visual prototypes from text for product designs since text is readily parsable. A designer can control the visual prototypes through text inputs until satisfying design parameters. However, systems supporting these learning models for image generation that are controlled encounter errors with inputting prompts that properly convey a design concept. For example, a designer wants to create a chair that feels “relaxing.” Directly requesting the learning models to generate a “relaxing chair” can lead to erroneous and unusable outputs since relaxing is a subjective term. Furthermore, learning models can overweight prompts for certain design parameters when lacking input types that are diverse, thereby hindering design goals.

Therefore, in one embodiment, a design system generates images of design areas to explore and augments ideation using multi-modal learning that searches for analogical suggestions. In particular, the multi-modal learning can search at scale and adapt suggestions within a design domain that is portable. In one approach, the analogical suggestions are generated by a transformer model such as a large language model (LLM) and a learning model that identify analogical relationships between inputted design parameters (e.g., a body line, an exterior contour, a product type, etc.). Furthermore, the design system can convert the image into a sketch by an edge model for modification and enhancements. In this way, the learning model may manipulate modified sketches of generated images through iterations that increase the accuracy with the design parameters. Accordingly, the design system generates a design using a transformer model and a learning model that reduces development cycles by processing text prompts and sketched strokes.

In one embodiment, a design system to generate designs using learning models for analogics that process text and sketch-based inputs is disclosed. The design system includes a memory storing instructions that, when executed by a processor, cause the processor to estimate analogical suggestions using a transformer model for a text prompt having design parameters. The instructions also include instructions to generate an image using a learning model for an expression selected from the analogical suggestions and a sketched stroke inputted. The instructions also include instructions to manipulate a modified sketch by the learning model and the modified sketch is derived from a sketched conversion of the image by an edge model.

In one embodiment, a non-transitory computer-readable medium for generating designs using learning models for analogics that process text and sketch-based inputs and including instructions that when executed by a processor cause the processor to perform one or more functions is disclosed. The instructions include instructions to estimate analogical suggestions using a transformer model for a text prompt having design parameters. The instructions also include instructions to generate an image using a learning model for an expression selected from the analogical suggestions and a sketched stroke inputted. The instructions also include instructions to manipulate a modified sketch by the learning model and the modified sketch is derived from a sketched conversion of the image by an edge model.

In one embodiment, a method for generating designs using learning models for analogics that process text and sketch-based inputs is disclosed. In one embodiment, the method includes estimating analogical suggestions using a transformer model for a text prompt having design parameters. The method also includes generating an image using a learning model for an expression selected from the analogical suggestions and a sketched stroke inputted. The method also includes manipulating a modified sketch by the learning model and the modified sketch is derived from a sketched conversion of the image by an edge model.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one embodiment of a design system that is associated with generating designs using a machine learning (ML) model from processing text prompts and sketched strokes.

FIG. 2 illustrates one embodiment of an interface generated by the design system as a tool for creating images from processing text prompts and sketched strokes.

FIG. 3A illustrates one embodiment of a transformer model and the ML model manipulating and generating images using text prompts and sketched strokes.

FIG. 3B illustrates one embodiment of a large language model (LLM) and a ML model manipulating and generating images using text prompts and sketched strokes with foreground extraction.

FIG. 4 illustrates one embodiment of a method that is associated with estimating analogical suggestions and generating designs using learning models from text prompts and sketched strokes.

### DETAILED DESCRIPTION

Systems, methods, and other embodiments associated with generating designs using learning models for analogics that process text and sketch-based inputs are disclosed herein. In various implementations, systems assisting designers with advanced graphic engines that augment images involve manual tasks (e.g., searches, research, etc.) that significantly increase development cycles. Other systems using learning models that generate designs encounter difficulties with interpreting disjoint inputs. For example, a learning model confuses an image of a car seat and prompt for an animal when designing a car seat for an animal. Such atypical requests can increase design cycles by demanding manual searches and reduce ideation as creative solutions go unexplored.

Therefore, in one embodiment, a design system generates an image using an expression selected from analogies generated by a machine learning (ML) model processing text prompts and sketched strokes. In particular, the design system includes a transformer model that estimates analogical suggestions involving design parameters (e.g., a body line, an exterior contour, a product type, etc.) and the ML model generates the image using an expression selected from the analogical suggestions and a sketched stroke. Here, the ML model can be a controlnet, a neural network (NN), and so on that extracts features from the expression and the sketched stroke for generating an image that intricately follows the design parameters. Furthermore, the design system allows designers to control design with text and mechanical inputs by controlling parameters with the sketched stroke (e.g., the body line of a vehicle). Therefore, designers can readily identify suggestions from disparate domains through analogic connections, such as nature, art, fashion, etc, for a product (e.g., a vehicle) with multi-modal inputs.

In one approach, the design system iteratively manipulates generated images with the ML model narrowing the expression to a near analogy. An iteration involves converting an image to a sketch with an edge detection model and modifying the sketch as a design alteration. For example, the modification involves removing strokes and background information through foreground extraction for narrowing the expression by the ML model. In this way, the modification can incorporate both similar seeds and form unique seeds with remixing for the ML model to generate images that ideate creatively while following the design parameters. Accordingly, the design system generates creative images by efficiently exploring analogics from text and graphic inputs that decrease design cycles and time.

It will be appreciated that for simplicity and clarity of illustration, where appropriate, reference numerals have been repeated among the different figures to indicate corresponding or analogous elements. In addition, the discussion outlines numerous specific details to provide a thorough understanding of the embodiments described herein. Those of skill in the art, however, will understand that the embodiments described herein may be practiced using various combinations of these elements.

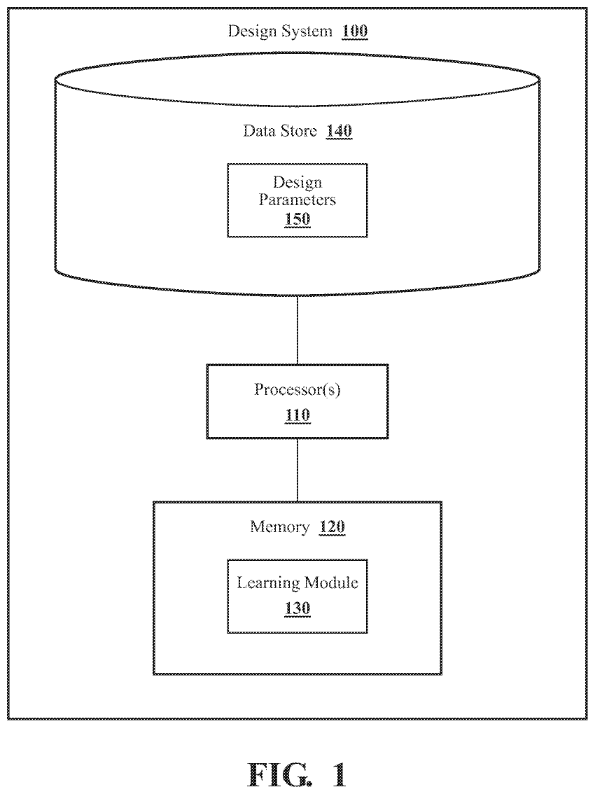

FIG. 1 illustrates one embodiment of a design system 100 that is associated with generating designs using a ML model from processing text prompts and sketched strokes. The design system 100 is shown as including a processor(s) 110 that the design system 100 may access through a data bus or another communication path. In one embodiment, the design system 100 includes a memory 120 that stores a learning module 130. The memory 120 is a random-access memory (RAM), a read-only memory (ROM), a hard-disk drive, a flash memory, or other suitable memory for storing the learning module 130. The learning module 130 is, for example, computer-readable instructions that when executed by the processor(s) 110 cause the processor(s) 110 to perform the various functions disclosed herein.

Moreover, in one embodiment, the design system 100 includes a data store 140. In one embodiment, the data store 140 is a database. The database is, in one embodiment, an electronic data structure stored in the memory 120 or another data store and that is configured with routines that can be executed by the processor(s) 110 for analyzing stored data, providing stored data, organizing stored data, and so on. Thus, in one embodiment, the data store 140 stores data used by the learning module 130 in executing various functions. In one embodiment, the data store 140 further includes the design parameters 150 that define inputs and modifications associated with the design system 100 generating an interface and analogical suggestions. Here, analogical suggestions are rapid identifications of relevant connections in nature, architecture, fashion, and so on for inputs. The design parameters 150 may be one of a body line, an exterior contour, scenery information, a product type, a product feel, and a product perception. For example, inputs are a text prompt to a transformer model and an output are analogical suggestions. Other inputs are an expression selected from the analogical suggestions and a sketched stroke to the ML model acquired through an interface. An output is a generated image from the ML model incorporating the expression and the sketched stroke of the generated image.

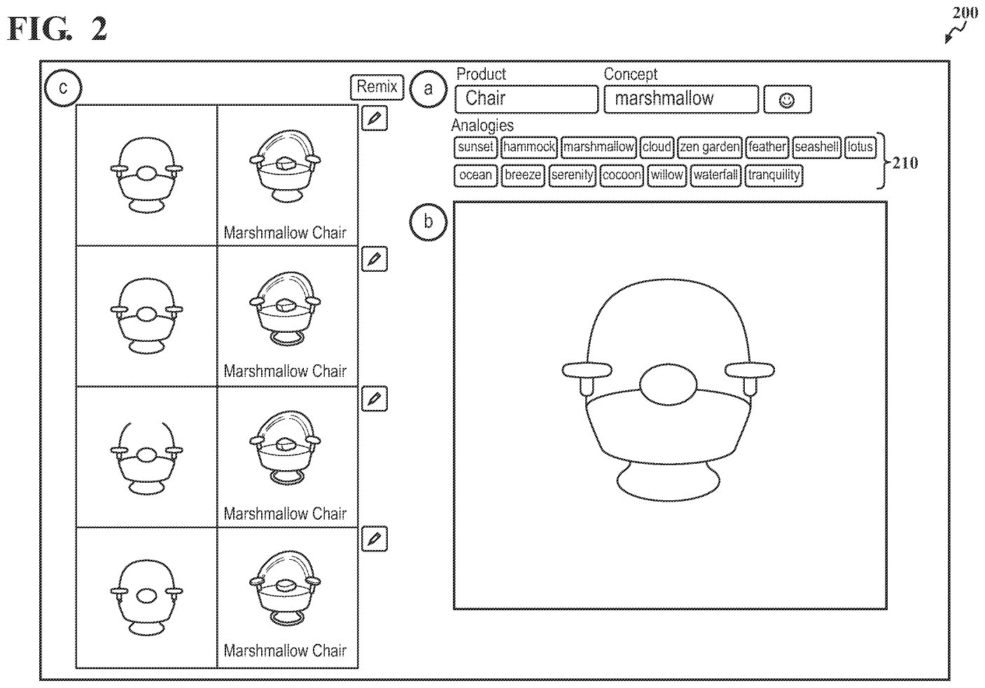

Now turning to FIG. 2, one embodiment of an interface 200 generated by the design system 100 as a tool for creating images from processing text prompts and sketched strokes is illustrated. The interface 200 may include: an analogical panel (a), a sketching panel (b), and an evolution panel (c). In one approach, the design system 100 recommends analogies for “a relaxing chair” that include “marshmallow,” “cloud,” “lotus,” and so on from the transformer model in output 210. In particular, the analogical panel (a) can include input fields for design parameters having a product and a design concept fields. The design system 100 receives a click on a think button from a design to generate analogical suggestions as inspirations for a product as a chair and a concept as marshmallow. Accordingly, a designer can select suggestions within the output 210 as the design concept and continue generating analogical suggestions as inspirations with the design system 100.

Furthermore, the sketching panel (b) may be an area on the interface 200 for outputting a sketch from an image generated by the ML model. Here, the ML model can be a controlnet, a NN, and so on that extracts features from the expression and the sketched stroke for generating an image intricately matching the design parameters 150. In one approach, the design system 100 isolates the image within the sketching panel (b) by removing background information, such as through foreground extraction using a network model (e.g., U2Net). The sketching panel (b) can also function as an area for modifying a sketch generated from the image as feedback to the ML model, thereby refining designs. As further explained below, the evolution panel (c) identifies varied forms of the image through iterations and remixes the expression associated with analogical suggestions using seeds (e.g., additional text, words, images, etc.) for enhancing design concepts. Therefore, the interface 200 provides a tool for generating analogical suggestions from text prompts and sketched strokes and outputting generated images including sketch representations, thereby improving design exploration and creativity for objects (e.g., vehicles).

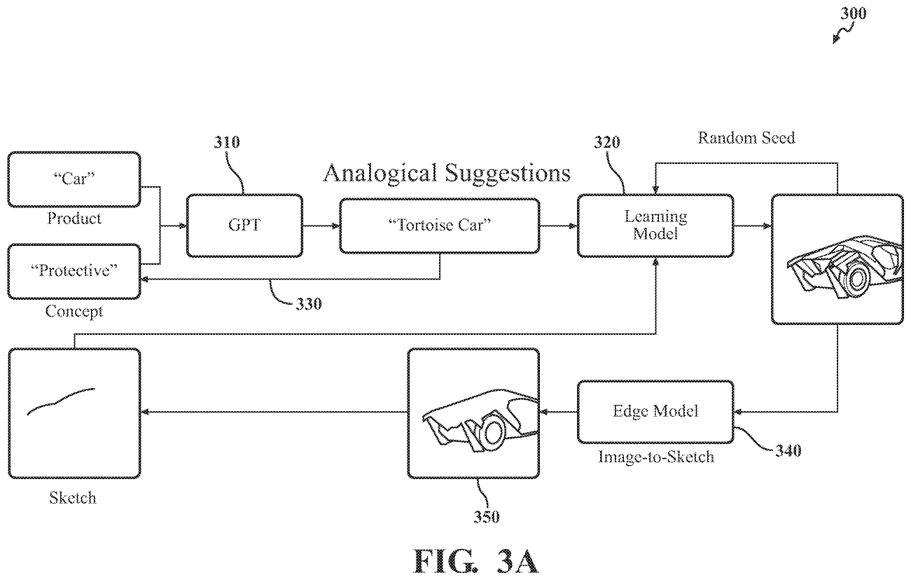

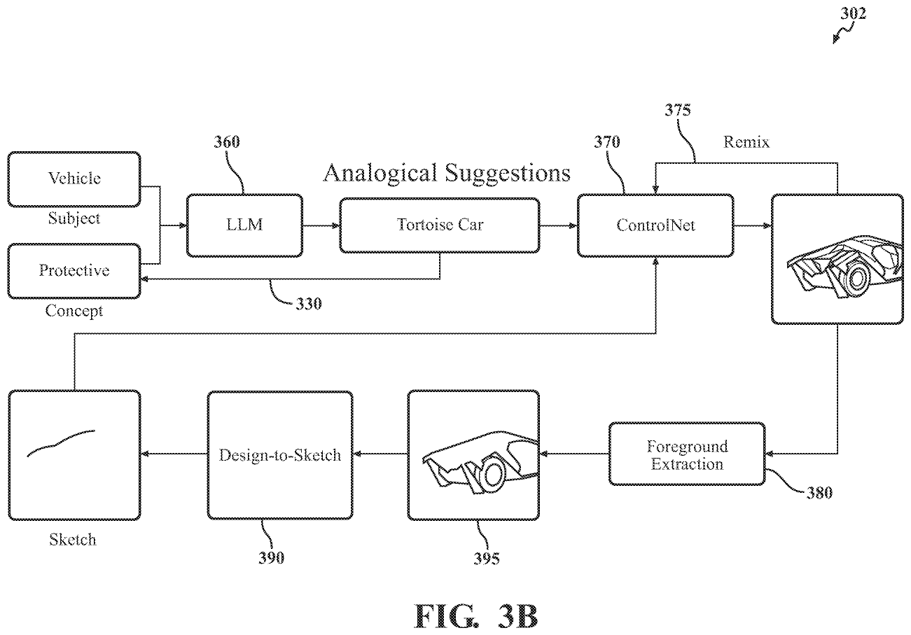

Referencing FIG. 3A, one embodiment of the transformer model and the ML model that manipulates and generates images using text prompts and sketched strokes associated with the interface 200 is illustrated. In various implementations, the learning module 130 is further configured to perform additional tasks. For example, the learning module 130 includes instructions that cause the processor 110 to recommend analogies that are visually-concrete according to the design parameters 150 representing product and design features through a sketch-to-image paradigm. As such, the pipeline 300 can implement the design system 100 and estimate analogical suggestions using a transformer model for a text prompt factoring the design parameters 150. The learning model 320 generates an image for an expression(s) selected from the analogical suggestions and a sketched stroke inputted. Furthermore, the learning model 320 manipulates a modified sketch and the modified sketch is derived from a sketched conversion of the image by the edge model 340.

Additionally, in one approach, the pipeline 300 includes a generative pre-trained transformer (GPT) 310 (e.g., GPT-3.5, GPT-4, etc. by OpenAI) as the transformer model that processes a prompt. For example, the prompt is “Think of interesting analogical inspirations to <concept> for designing a <product>. <examples of analogical designs>. <formatting prompts>.” Here, the GPT 310 may function as a large language model (LLM) where a transformer model of a NN uses attention rather than previous recurrence and convolution operations. Attention mechanisms allow the GPT 310 to selectively focus on the product and the concept text segments and identify analogical relationships that are creative. In one approach, textual outputs associated with the GPT 310 seed new concepts through the feedback loop 330 associated with the analogical inspirations. A seed can be random or similar design goals (e.g., text, images, etc.) that assist the GPT 310 with identifying deterministic and consistent responses to inputs. In one approach, the GPT 310 estimates the analogical suggestions with scenery information (e.g., a landscape design) for the design parameters 150 before the learning model 320 generates the image from the expression and the sketched stroke.

Moreover, the design system 100 generates the sketching panel (b) that allows sketching on a canvas and guiding image generation. In various implementations, the learning module 130 invokes the learning model 320 (e.g., a controlnet, a NN, etc.) to generate images by processing a sketch and the prompt: “a <concept>-inspired <product>, <prompt engineering keywords>.” Once an expression is selected from the analogical suggestions, additional strokes received by the pipeline 300 can trigger the generation of a new image. Furthermore, the generated images can be fed back to the learning model 320 as random seeds until convergence upon a design concept. Here, a seed can assist the learning model 320 with identifying deterministic and consistent responses to generated images and the additional strokes. In one approach, the random seeds are kept within a constant range for retaining similar image generations between sketched strokes. The feedback may also involve the learning model 320 factoring semantics (e.g., color) for converging upon a design associated with an expression and a sketch. In one approach, a designer undoes strokes and erases sketched lines on the sketching panel (b) for triggering the learning model 320 to generate a new image. This action may involve partially, completely, etc. clearing the canvas that functions as a diverse seed for the learning model 320. Accordingly, the pipeline 300 shifts the focus on iterative sketching rather than textual tuning with the GPT 310, thereby accelerating and refining designs through a sketch-centric paradigm while increasing creativity.

The sketching panel (b) also can display a sketch laid under a sketching canvas as the sketching guidelines 350. Here, the sketching guidelines can be generated with an edge model 340 after receiving a click on the convert-to-sketch, such as an edge detection (ED) model. For example, the edge model 340 is a holistically-nested edge detection (HED) model that detects hard edges, soft edges, etc. from an image using hierarchical representations within a NN. As such, the learning module 130 converts a generated image into a sketch through the edge model 340. In this way, a designer can build upon a generated image from the sketch and restart a feedback loop of the sketch-to-image paradigm. Therefore, this capability allows rapid design prototyping through iterative sketching and image generation by the learning model 320.

In one approach, the learning model 320 uses modified sketches to iteratively manipulate generated images and narrow the expression towards a near analogy that is reliable. For instance, iterative manipulations alter a modified sketch having removed strokes that form unique seeds for narrowing the expression by the learning model 320. In this way, adding or removing sketched strokes as inputs to the learning model 320 transitions early phases having wild analogic suggestions towards later phases showing near analogies. Therefore, the pipeline 300 reduces search and design times for creative products while allowing generative sketch modifications that are advanced.

Turning now to the evolution panel (c), the design system 100 allows scrolling through records of previously generated images that are selected designs. A record may display a rendered sketch by the design system 100, the product and the concept, and the generated image. In various implementations, the designer clicks a remix button to generate design variations by remixing a selected expression from analogical suggestions. The design system 100 can generate variations by randomly creating different or similar seeds associated with the design parameters 150. Similar to previous descriptions, the seeds can be kept constant within a range to retain consistent image generations between sketched strokes.

Regarding the pipeline 302 in FIG. 3B, the design system 100 implements a LLM 360 that receives text prompts and a controlnet 370 processes a sketch for manipulating and generating images using foreground extraction 380. The pipeline 302 receives text prompts and a sketch for rendering a visual design. In one approach, a designer specifies a design subject (e.g., vehicle) and a design concept (e.g., protective). The LLM 360 generates analogical suggestions as inspirations for further design development. Here, the design system 100 prompts the LLM 360 to describe the design principles for the design subject. For example, the design system 100 requests the LLM 360 to describe the design principles in design <subject> within a brief paragraph. This serves as a “synthetic context” for the LLM 360 to generate viable and thoughtful inspirations.

Subsequently, the design system 100 prompts the LLM 360 to derive inspirations from a domain (e.g., nature, architecture, fashion, etc.) given the design principles. For instance, a designer has a project to design a <subject>. The design principles in design <subject> may be <design principles from initial processing>. As such, the prompt can derive inspirations for the design <subject> and convey a sensible <concept> from the domain. Furthermore, the design system 100 can instruct the LLM 360 to output an answer in a bullet-point list of items such as [item 1\nitem2 . . . \nitem3].

Moreover, the design system 100 receives a sketch (e.g., one or multiple strokes) to guide the visual generation. The controlnet 370 can receive the designer-selected inspiration (i.e., text) and the sketch (i.e., image) for processing with a model using stable diffusion to generate a rendered design. In various implementations, a stable diffusion model includes a variational autoencoder (VAE) that compresses an image from a pixel space to a latent space having reduced dimensionality, thereby capturing improved semantics. The model iteratively applies Gaussian noise to the compressed latent representation during forward diffusion. A U-Net denoises the output from forward diffusion backwards to obtain a latent representation. The VAE decodes and generates a final image by converting the latent representation back into the pixel space.

In pipeline 302, the design system 100 outputs different designs with additional sketches, thereby making the creation process iterative and visual unlike text-prompt engineering. In one approach, the controlnet 370 uses the same seed for re-generation with the additional sketches to maintain consistency over time. Furthermore, the designer may trigger a remix 375 to change seeds and generate more diverse designs. As an additional improvement, the foreground extraction 380 may use a network model (e.g., U2Net) to crop and isolate a generated design from the background. In this way, design-to-sketch 390 can accurately generate key guidelines from the cropped design 395, such as through semantic segmentation and edge detection using an edge model. As such, a designer can build upon the generated design from the sketch and restart a feedback loop with the design system 100. Therefore, the design system 100 reduces time and improves prototyping through iterative sketching, image generation, and seed remixing.

Comparing FIG. 2 and FIG. 3A, the design system 100 in FIG. 2 generates sketches and images of chairs using an input of text inputs chair<product> and marshmellow<concept> along with the sketch “marshmallow chair.” However, the design system 100 in FIG. 3A generates an automobile body in sketched-form using inputs car<product> and protective<concept> and a sketch having a body line. A tortoise car may be an analogical suggestion for protective<concept> generated by the design system 100. As such, the design system 100 adapts and creates designs from diverse domains for generalized inputs. Thus, the design system 100 outputs analogical suggestions of design areas using the learning model 320 that improve and accelerate object searching and development that is creative.

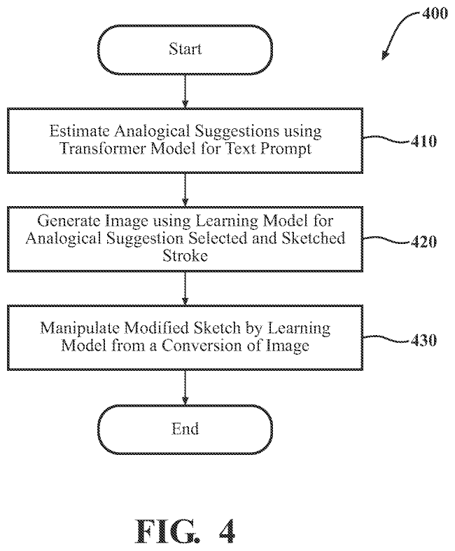

Now turning to FIG. 4, one embodiment of a method 400 that is associated with generating designs using learning models for analogics from text prompts and sketch strokes is illustrated. Method 400 will be discussed from the perspective of the design system 100 of FIG. 1. While method 400 is discussed in combination with the design system 100, it should be appreciated that the method 400 is not limited to being implemented within the design system 100 but is instead one example of a system that may implement the method 400.

At 410, the design system 100 estimates analogical suggestions using a transformer model for a text prompt. For example, the design system 100 acquires product and concept features as the design parameters from corresponding fields within an interface. The design parameters may be one of a body line, an exterior contour, scenery information, a product type, a product feel, and a product perception. Furthermore, as previously explained, the transformer model can be a LLM (e.g., GPT) that processes a textual prompt and initially generates wild analogics as various and diverse expressions. The LLM can selectively focus on variable portions of the product and the concept textual features and identify analogical relationships that are relevant and creative. As such, analogical suggestions are rapid identifications of connections in nature, consumer articles, architecture, fashion, and so on for inputs. Outputs of the LLM can also be fed back as seeds for generating new concepts with consistency, thereby forming a refinement loop. In one approach, as previously explained the LLM incorporates scenery information (e.g., a landscape design) for the design parameters to estimate the analogical suggestions before a learning model generates an image from a selected expression and a sketched stroke. In this way, a generated image include additional contextual information, thereby further reducing development time.

At 420, the learning module 130 generates an image using the learning model for an analogical suggestion selected and a sketched stroke. For example, the learning model (e.g., controlnet, a NN, etc.) processes an expression selected from analogical suggestions after the transformer model iteratively seeds textual outputs as new concepts through a feedback loop. Here, the random or similar seeds may be kept within a range to retain similar image generations between sketched strokes. In one approach, generated images are fed back as random seeds to the learning model until a design convergence occurs. For instance, this involves the learning model factoring semantics (e.g., color) for converging upon a design associated with an expression and a sketch.

Moreover, the design system 100 generates a sketching panel that receives the sketched stroke for guiding image generation. In various implementations, the learning module 130 invokes the learning model to generate images by processing the sketched stroke that is a line and the text prompt. Supplemental strokes received by the design system 100 can trigger the generation of a new image as a design loop after an expression is selected from the analogical suggestions. Furthermore, undoing strokes or erasing sketched lines can trigger the learning model to generate a new image. Thus, iterative steps adapt to the design phase within a design cycle through sketching rather than text inputs.

At step 430, the learning module 130 manipulates a modified sketch by the learning model from a conversion of the image. Here, a sketch is generated by an edge model, such as an ED model. For example, the edge model is a HED that detects edges from an image using a NN having hierarchical representations as layers. As previously explained, the learning model may use sketches that are modified or enhanced to narrow the expression towards an accurate analogy through iteratively manipulating generated images. In one approach, iterative manipulations alter a modified sketch having removed strokes and background information through foreground extraction using a network model, thereby forming unique and advanced seeds for the learning model for narrowing the expression while also expanding creativity. As such, the learning model transitions early phases having analogic suggestions that are wild to complete phases showing near analogies removing sketched strokes. Therefore, the design system 100 allows a sketch-centered approach for generative design through iterative sketching rather than tuning with text engineering, thereby reducing search and design times for creative products.

Detailed embodiments are disclosed herein. However, it is to be understood that the disclosed embodiments are intended as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Furthermore, the terms and phrases used herein are not intended to be limiting but rather to provide an understandable description of possible implementations. Various embodiments are shown in FIGS. 1-4, but the embodiments are not limited to the illustrated structure or application.

The flowcharts and block diagrams in the figures illustrate the architecture, functionality, and operation of possible implementations of systems, methods, and computer program products according to various embodiments. In this regard, a block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components, and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein.

The systems, components, and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a ROM, an EPROM or flash memory, a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

Generally, modules as used herein include routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an ASIC, a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, radio frequency (RF), etc., or any suitable combination of the foregoing. Computer program code for carrying out operations for aspects of the present arrangements may be written in any combination of one or more programming languages, including an object-oriented programming language such as Java™, Smalltalk™, C++, or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all combinations of one or more of the associated listed items. As an example, the phrase “at least one of A, B, and C” includes A, B, C, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A design system comprising:
a memory storing instructions that, when executed by a processor, cause the processor to:
estimate analogical suggestions using a transformer model for a text prompt having design parameters;
generate an image using a learning model for an expression selected from the analogical suggestions and a sketched stroke inputted; and
manipulate a modified sketch by the learning model and the modified sketch is derived from a sketched conversion of the image by an edge model.

2. The design system of claim 1, wherein the instructions to manipulate the modified sketch further include instructions to iterate manipulations with the learning model by narrowing the expression to a near analogy.

3. The design system of claim 2, wherein the instructions to iterate the manipulations further include instructions to alter the modified sketch having removed strokes and background information that form unique seeds and remix design seeds associated with the image for narrowing the expression by the learning model.

4. The design system of claim 1, wherein the instructions to generate the image using the learning model further include instructions to remix the expression to generate varied forms of the image from randomized seeds associated with the design parameters.

5. The design system of claim 1, wherein the edge model is a holistically-nested edge detection (HED) model that detects edges from the image using hierarchical representations within a neural network.

6. The design system of claim 1, wherein the instructions to estimate the analogical suggestions further include instructions to:
compute scenery information following the design parameters before the learning model generates the image from the expression and the sketched stroke.

7. The design system of claim 1, wherein the instructions to manipulate the modified sketch further include instructions to:
extract the image from a foreground of a view using a network model; and
the learning model is one of a controlnet and a neural network that extracts features from the expression and the sketched stroke.

8. The design system of claim 1, wherein the instructions to estimate the analogical suggestions further include instructions to:
derive design principles for a domain and the design parameters from the transformer model; and
the design parameters are associated with one of a body line, an exterior contour, scenery information, a product type, a product feel, and a product perception and the analogical suggestions are verbal.

9. A non-transitory computer-readable medium comprising:
instructions that when executed by a processor cause the processor to:
estimate analogical suggestions using a transformer model for a text prompt having design parameters;
generate an image using a learning model for an expression selected from the analogical suggestions and a sketched stroke inputted; and
manipulate a modified sketch by the learning model and the modified sketch is derived from a sketched conversion of the image by an edge model.

10. The non-transitory computer-readable medium of claim 9, wherein the instructions to manipulate the modified sketch further include instructions to iterate manipulations with the learning model by narrowing the expression to a near analogy.

11. The non-transitory computer-readable medium of claim 10, wherein the instructions to iterate the manipulations further include instructions to alter the modified sketch having removed strokes and background information that form unique seeds and remix design seeds associated with the image for narrowing the expression by the learning model.

12. The non-transitory computer-readable medium of claim 9, wherein the instructions to generate the image using the learning model further include instructions to remix the expression to generate varied forms of the image from randomized seeds associated with the design parameters.

13. A method comprising:
estimating analogical suggestions using a transformer model for a text prompt having design parameters;
generating an image using a learning model for an expression selected from the analogical suggestions and a sketched stroke inputted; and
manipulating a modified sketch by the learning model and the modified sketch is derived from a sketched conversion of the image by an edge model.

14. The method of claim 13, wherein manipulating the modified sketch further includes iterating manipulations with the learning model by narrowing the expression to a near analogy.

15. The method of claim 14, wherein iterating the manipulations further includes altering the modified sketch having removed strokes and background information that form unique seeds and remix design seeds associated with the image for narrowing the expression by the learning model.

16. The method of claim 13, wherein generating the image using the learning model further includes remixing the expression to generate varied forms of the image from randomized seeds associated with the design parameters.

17. The method of claim 13, wherein the edge model is a holistically-nested edge detection (HED) model that detects edges from the image using hierarchical representations within a neural network.

18. The method of claim 13, wherein estimating the analogical suggestions further includes:
computing scenery information following the design parameters before the learning model generates the image from the expression and the sketched stroke.

19. The method of claim 13, wherein manipulating the modified sketch further includes:
extracting the image from a foreground of a view using a network model; and
the learning model is one of a controlnet and a neural network that extracts features from the expression and the sketched stroke.

20. The method of claim 13, wherein estimating the analogical suggestions further includes:
deriving design principles for a domain and the design parameters from the transformer model; and
the design parameters are associated with one of a body line, an exterior contour, scenery information, a product type, a product feel, and a product perception and the analogical suggestions are verbal.
